(19) United States
(12) Patent Application Publication
(10) Pub. No.: US 2014/0167020 A1
(43) Pub. Date: Jun. 19, 2014

(54) Passive Matrix Organic Light Emitting Diodes

(71) Applicant: SRI International, Menlo Park, CA (US)

(72) Inventors: Yijian Shi, Mountain View, CA (US); Qianfei Xu, Mountain View, CA (US); William Siu-Keung Chu, Newark, CA (US)

(73) Assignee: SRI INTERNATIONAL, Menlo Park, CA (US)

(21) Appl. No.: 14/164,180

(22) Filed: Jan. 25, 2014

Related U.S. Application Data
(63) Continuation of application No. PCT/US12/50498, filed on Aug. 12, 2012.
(60) Provisional application No. 61/523,083, filed on Aug. 12, 2011.
(60) Provisional application No. 61/523,090, filed on Aug. 12, 2011.

(51) Int. Cl. H01L 27/32

(52) U.S. Cl. CPC H01L 27/329
USPC 257/40; 438/34

(57) ABSTRACT

A passive matrix OLED display comprises an array of individually addressable OLED pixels arranged in column and row lines in an imaging area of the display, wherein at least one OLED pixel comprises at least one rectifying component connected in series with an electroluminescent diode, and wherein the at least one OLED pixel has an extended pixel on-time compared with a similar pixel lacking the at least one rectifying component.

### CROSS-REFERENCE TO RELATED APPLICATIONS

This application is a continuation of PCT/US12/50498; filed: Aug 12, 2012, which claims priority to Nos. 61/523,083 and 61/523,090, both filed Aug 12, 2011, the disclosures of which are incorporated herein by reference in their entireties.

### INTRODUCTION

OLED displays can be classified as passive matrix (PM) and active matrix (AM) displays depending on how the display is addressed. Generally speaking, AMOLED displays have better efficiency and longer lifetime than PMOLED, but much higher product cost. The high cost of AMOLED comes mainly from the required TFT backplane. Due to some limitations inherent to the materials, the TFT backplanes are expensive to make. On the other hand, existing TFT technologies are unable to deliver enough current to drive larger OLED panels. Therefore, OLED panels of 20″ and above are currently not commercially available.

PMOLEDs are less expensive than AMOLEDs. However, the performance of PMOLED is not satisfactory: PMOLED has a shorter lifetime, limited resolution and size, and is less power efficient. Improving PMOLED's performance can significantly increase its commercial value and widen the field of use for PMOLED technology.

Relevant art includes U.S. 20060091794, U.S. 20070114522, and U.S. 20070152923.

### SUMMARY OF THE INVENTION

In one aspect, the invention provides a passive matrix OLED display comprising an array of individually addressable OLED pixels arranged in column and row lines in an imaging area of the display, wherein at least one OLED pixel comprises at least one rectifying component connected in series with an electroluminescent diode, and wherein the at least one OLED pixel has an extended pixel on-time compared with a similar pixel lacking the at least one rectifying component.

Particular embodiments include:
wherein the at least one rectifying component accounts for at least 50% of the overall capacitance of the pixel;
wherein the at least one rectifying component has a rectification ratio of greater than 1;
wherein the forward resistance of the at least one rectifying component is equal to the forward resistance of the electroluminescent diode;
wherein the at least one rectifying component has an I/V response curve with a slope greater than 2 in the forward biased region after the cut-in voltage;
wherein the at least one rectifying component has minimal characteristic forward resistance;
wherein the OLED is a COLED and comprises a cavity;
wherein the cavity extends through an electroluminescent layer and a dielectric layer;
wherein the at least one rectifying component has accounts for at least 50% of the overall capacitance of the pixel, and wherein the forward resistance of the at least one rectifying component is equal to the forward resistance of the electroluminescent diode;
the at least one rectifying component has a rectification ratio of greater than 1, and wherein the OLED is a COLED and comprises a cavity; and
wherein the at least one rectifying component has accounts for at least 50% of the overall capacitance of the pixel, and wherein the at least one OLED pixel has an extended pixel on-time compared with a similar pixel lacking the at least one rectifying component.

In another aspect, the invention provides a method for forming a passive matrix OLED display comprising a plurality of individually addressable OLED pixels arranged in column and row lines on a substrate in an imaging area of the display, the method comprising: forming each OLED pixel in the plurality of pixels by series-connecting an electroluminescent diode and at least one rectifying component, wherein the rectifying component increases the on time of the OLED pixel.

In particular embodiments, the substrate functions as an anode.

In another aspect, the invention provides a device comprising, in order: (a) a substrate layer (b) a bottom electrode layer; (c) one or more semiconductor layers; (d) a pixel bottom electrode layer; (e) a dielectric layer; (f) a pixel top electrode layer; and (g) an electroluminescent layer, and further comprising at least one cavity extending through the pixel top electrode and through the dielectric layer, wherein electroluminescent material from the electroluminescent layer extends into the at least one cavity and contacts the dielectric layer, the pixel top electrode layer, and the bottom electrode layer.

In another aspect, the invention provides a device comprising, in order: (a) a substrate; (b) a bottom electrode layer; (c) a dielectric layer; (d) a pixel top electrode layer; and (e) an electroluminescent layer, and further comprising: (i) at least one cavity extending through the pixel top electrode and through the dielectric layer, and defining a pattern in the pixel top electrode layer; and (ii) a semiconductor layer contacting the pixel top electrode layer and separating the pixel top electrode layer from the electroluminescent layer, wherein electroluminescent material from the electroluminescent layer extends into the at least one cavity and contacts the dielectric layer, the pixel top electrode layer, and the bottom electrode layer.

In another aspect, the invention provides a pixel in an OLED device comprising, in order: (a) a transparent substrate; (b) an anode; (c) a pixel element comprising an OLED stack and a transparent thin film diode, wherein the thin film diode increases the capacitance of the pixel; and (d) a cathode.

In another aspect, the invention provides an OLED display comprising an array of individually addressable OLED pixels arranged in column and row lines in an imaging area of the display, wherein: at least one OLED pixel comprises, in order, a bottom electrode layer, a dielectric layer, a pixel top electrode layer, and an electroluminescent layer, and further comprises a cavity extending through the dielectric layer and the top electrode layer; and (b) the electroluminescent layer extends into the cavity and contacts the dielectric layer, the pixel top electrode layer, and the bottom electrode layer; and

In particular embodiments:
the imaging area of the display has a diagonal dimension greater than 5 inches;
the OLED display further comprises a cathode layer having a thickness greater than 1 micron;
the OLED display further comprises an anode layer made of an anode material having a conductivity greater than ITO;
the OLED display further comprises a dielectric layer made of a dielectric material having a k-value greater than 1; and/or
the imaging area of the display has a diagonal dimension greater than 5 inches and wherein the OLED display further comprises a dielectric layer made of a dielectric material having a k-value greater than 1.

### DESCRIPTION OF PARTICULAR EMBODIMENTS OF THE INVENTION

In one aspect, the invention provides a passive matrix OLED display comprising an array of individually addressable OLED pixels arranged in column and row lines in an imaging area of the display.

At least one OLED pixel comprises at least one rectifying component connected in series with an electroluminescent diode. In some embodiments, each OLED pixel in the array of OLED pixels comprises at least one rectifying component connected in series with an electroluminescent diode.

The rectifying component of an OLED pixel is effective to extend the pixel on-time compared with a similar pixel lacking the rectifying component. For example, pixel is similar but lacking the rectifying component when the pixel contains all of the same components (e.g., electroluminescent diode, optional cavity, substrate, etc.) except for a component that functions as a rectifier. For example, a similar pixel to an OLED pixel of the invention can contain an electroluminescent diode and a cavity, but lacks a separate rectifying component (i.e., one other than the electroluminescent diode, which is itself a rectifier).

Traditional PMOLEDs use a scanning mode that switches on the pixels line by line alternatively within each scanning cycle, the pixel's “on-time” (1/fₙ second, where f is the scanning frequency and n is the total number of lines of the panel) is much shorter then the pixel's “off-time” ((n−1)/fₙ second, therefore the ration of on-time to off-time is 1/(n−1)). In order to achieve a certain average brightness B₀, the pixel transient brightness B (pixel brightness is when the pixel is at the “on” state) required is much higher than B₀, i.e. B=n×B₀>>B₀. Because the pixels of a PMOLED require operation at a much higher brightness, the device lifetime and efficiency are significantly reduced.

Each OLED pixel also has a capacitive component. Thus, the PM driving mode involves charging and discharging of the capacitor in addition to generate the light emission from the light-emitting diode (LED) device. Therefore, the total power delivered by a driver includes three components, the power to generate the light (P_{light}), the power to charge the capacitor (P_{cap}), and the power consumed by the resistance of the electrode (Pᵣₑₛ). As the panel and pixel sizes increase, the P_{cap} component increases rapidly.

In some embodiments, the inventive devices recover part or all of the P_{cap} component and convert it to P_{light}. In this manner, the power efficiency of the inventive PMOLEDs is significantly enhanced.

The inventive designs use a rectifying element such as a diode connected in series with the electroluminescent diode of each display pixel. The working principle of this design is as follows: during the on-state, the OLED pixel assumes the function of a conventional PMOLED; during the off-state, the additional rectifying element prevents the OLED to discharge via the external circuitry. Therefore, the charges stored in the capacitor will be forced to discharge via the LED to generate additional light emission.

The inventive designs avoid or reduce P_{cap} to be wasted by discharging via the external circuitry. Instead, the electric power stored in the capacitor is used to continue driving the LED pixel for a longer period of time (until the capacitor is fully discharged). As a result, the pixel's on-time is extended and the power efficiency is improved. In some embodiments the longer on-time requires a lower B, resulting in a better device lifetime and efficiency.

The inventive devices extend the pixel's “on-time”, thereby allowing B to be reduced and extending device lifetime and efficiency. The on-time is extended because the rectifying element reduces the amount of, or eliminates entirely, the capacitive voltage that is discharged via the external circuitry, and similarly increases the amount of capacitive voltage that is discharged via the electroluminescent diode of the pixel. In some embodiments, at least 25, 50, 75, 90, or 90% of the capacitive voltage of the pixel is discharged as light from the electroluminescent diode. In some embodiments, substantially all of the capacitive voltage of the pixel is discharged as light from the electroluminescent diode.

In some embodiments, the at least one rectifying component accounts for at least 25, 50, 55, 60, 65, 70, or 75% of the overall capacitance of the pixel. In some embodiments, the at least one rectifying component increases the overall capacitance of the pixel, and in other embodiments the at least one rectifying component does not increase the overall capacitance of the pixel.

In some embodiments, the at least one rectifying component has a rectification ratio of greater than 1, 10, 10², 10³, 10⁴, or 10⁵. The rectification ratio can be defined as Rm/Rc+1 where Rm is the characteristic leakage resistance and Rc is the characteristic resistance of the physical diode. Alternatively or in addition, the rectification ratio can be defined as the maximum-to-minimum-current-ratio.

In some embodiments, the forward resistance of the at least one rectifying component is equivalent to the forward resistance of the electroluminescent diode. In some embodiments, the forward resistance of the at least one rectifying component is not more than 5, 10, 15, 20, or 25% greater than the forward resistance of the electroluminescent diode. In some embodiments, the forward resistance of the at least one rectifying component is at least 5, 10, 25, 50, or 75% less than the forward resistance of the electroluminescent diode. In some embodiments, the at least one rectifying component has minimal characteristic forward resistance. In some embodiments, the at least one rectifying component has substantially zero forward resistance.

In some embodiments the at least one rectifying component has, in the forward biased region after the cut-in voltage, an I/V response curve with an average slope at least 2, 3, 4, or 5 times greater than the average slope of the I/V response curve of the similar pixel lacking the at least one rectifying component. In some embodiments, the I/V response curve of the at least one rectifying component is characteristic of a rectifying component and is distinct from a resistive (i.e., current limiting) element.

In some embodiments, the OLED is a cavity OLED (COLED) and comprises a cavity. In some such embodiments the cavity extends through an electroluminescent layer and a dielectric layer. Examples of COLED devices are provided in U.S. Pat. No. 6,593,687 (which describes a COLED-A structure, having a non-transparent substrate and being top-emitting), and U.S. Patent Application Publication No. 2008/0248240 (which describes a COLED-B structure, having a transparent substrate and being bottom-emitting), the contents of which are incorporated herein by reference.

The rectifying element can be connected to the “−” or to the “+” end of the OLED pixel. That is, the rectifying element is in series with the electroluminescent diode, and can be electrically and/or physically positioned between the electroluminescent diode and the “−” terminal, or between the electroluminescent diode and the “+” terminal.

The rectifying element can be any electronic component that can function as a rectifier, such as various types of diodes and transistors including thin-film diodes and thin-film transistors.

For the COLED-A structure, the designs of the invention allow the capacitance of the pixel to be increased by using a high-k material as the dielectric layer. High-k materials are those with a k value greater than, for example, SiO₂. In some embodiments, materials and design specifications (e.g., layer thicknesses, etc.) are selected to provide for maximum pixel capacitance.

In another aspect, the invention provides a method for forming a passive matrix OLED display comprising a plurality of individually addressable OLED pixels arranged in column and row lines on a substrate in an imaging area of the display. The method comprises forming each OLED pixel in the plurality of pixels by series-connecting an electroluminescent diode and at least one rectifying component. As described above, the rectifying component increases the on time of the OLED pixel relative to a pixel lacking a rectifying component.

In particular embodiments of the substrate functions as an anode.

In another aspect, the invention provides a device comprising, in order: (a) a substrate layer (b) a bottom electrode layer; (c) one or more semiconductor layers; (d) a pixel bottom electrode layer; (e) a dielectric layer; (f) a pixel top electrode layer; and (g) an electroluminescent layer, and further comprising at least one cavity extending through the pixel top electrode and through the dielectric layer, wherein electroluminescent material from the electroluminescent layer extends into the at least one cavity and contacts the dielectric layer, the pixel top electrode layer, and the bottom electrode layer.

Materials suitable for the various layers are described, for example, in U.S. Patent Application Publication No. 2008/0248240. For example, the substrate can be a non-transparent material such as a metal, or a transparent material such as ITO or silicon dioxide. In some cases the substrate functions also as an electrode.

In another aspect, the invention provides a device comprising, in order: (a) a substrate; (b) a bottom electrode layer; (c) a dielectric layer; (d) a pixel top electrode layer; and (e) an electroluminescent layer, and further comprising: (i) at least one cavity extending through the pixel top electrode and through the dielectric layer, and defining a pattern in the pixel top electrode layer; and (ii) a semiconductor layer contacting the pixel top electrode layer and separating the pixel top electrode layer from the electroluminescent layer, wherein electroluminescent material from the electroluminescent layer extends into the at least one cavity and contacts the dielectric layer, the pixel top electrode layer, and the bottom electrode layer.

In another aspect, the invention provides a pixel in an OLED device comprising, in order: (a) a transparent substrate; (b) an anode; (c) a pixel element comprising an OLED stack and a transparent thin film diode, wherein the thin film diode increases the on-time of the pixel compared with a similar pixel lacking the thin film diode; and (d) a cathode.

In another aspect, the invention provides an OLED display comprising an array of individually addressable OLED pixels arranged in column and row lines in an imaging area of the display, wherein: at least one OLED pixel comprises, in order, a bottom electrode layer, a dielectric layer, a pixel top electrode layer, and an electroluminescent layer, and further comprises a cavity extending through the dielectric layer and the top electrode layer; and (b) the electroluminescent layer extends into the cavity and contacts the dielectric layer, the pixel top electrode layer, and the bottom electrode layer.

In particular embodiments:
the imaging area of the display has a diagonal dimension greater than 5, 10, 15, or 20 inches. In some embodiments, the imaging area of the display has at least 500, 750, or 1000 rows of pixels;
the OLED display further comprises a cathode layer having a thickness greater than 0.1, 1, 5, 10, or 50 microns;
the OLED display further comprises an anode layer made of an anode material having a conductivity greater than ITO;
the OLED display further comprises a dielectric layer made of a dielectric material having a k-value greater than 1, 10, or 100;
the at least one OLED pixel comprises a plurality of cavities;
the at least one OLED pixel further comprises a substrate, wherein in some embodiments the substrate is transparent and in some embodiments the substrate is opaque;
emission from the OLED pixels originates substantially entirely from the cavities.

In some embodiments, the rectifying component differs from an organic diode in that it is an inorganic diode such as Si or metal oxide based diode.

In some embodiments, such as COLED-B structures, the inventive structures are not stacked structures, in that they do not involve stacking the rectifier element with the OLED pixel. Instead, the device involves putting the rectifier on the side, similar to the case of active matrix TFT backplane. Such embodiments are similar to the passive matrix LCD (i.e., the 1st generation of LCD).

The inventive designs such as PM COLED-A structures enable a combination of low cost, large size manufacturing while reducing the powder consumption and prolonging the lifetime of the display. COLED-A devices are significantly more power efficient than the conventional OLED. They can operate at much higher brightness for the same current density, and the electrodes have much higher conductivity associated with significantly better heat dissipation.

The higher average brightness results from the pixel remaining lit for a certain period of time after it is switched off (external driving voltage switched off). Faster switching time is also observed: when switching a row of pixels from the on-state to the off-state, the external driver circuitry will need to quickly switch the cathode voltage from a negative number to zero (or more frequently to a positive number), which may result in a huge discharging current from the pixels. With the rectifying component, this discharging current is reduced by several orders of magnitudes and therefore the switching times are significantly reduced. Furthermore, lower power consumption is observed: since discharging current through external (driver) circuitry generates heat, reducing such discharging current increases the efficiency.

The invention encompasses all combinations of recited particular and preferred embodiments. It is understood that the examples and embodiments described herein are for illustrative purposes only and that various modifications or changes in light thereof will be suggested to persons skilled in the art and are to be included within the spirit and purview of this application and scope of the appended claims. All publications, patents, and patent applications cited herein, including citations therein, are hereby incorporated by reference in their entirety for all purposes.

What is claimed is:

1. A passive matrix OLED display comprising an array of individually addressable OLED pixels arranged in column and row lines in an imaging area of the display, wherein: at least one OLED pixel comprises at least one rectifying component connected in series with an electroluminescent diode, and wherein the at least one OLED pixel has an extended pixel on-time compared with a similar pixel lacking the at least one rectifying component.

2. The passive matrix OLED display of claim 1, wherein:
a) the at least one rectifying component accounts for at least 25% of the overall capacitance of the pixel.

3. The passive matrix OLED display of claim 1, wherein:
b) the at least one rectifying component has a rectification ratio of greater than 1.

4. The passive matrix OLED display of claim 1, wherein:
c) the forward resistance of the at least one rectifying component is equal to the forward resistance of the electroluminescent diode.

5. The passive matrix OLED display of claim 1, wherein:
d) the at least one rectifying component has, in the forward biased region after the cut-in voltage, an I/V response curve with an average slope at least 2 times greater than the average slope of the I/V response curve of the similar pixel lacking the at least one rectifying component.

6. The passive matrix OLED display of claim 1, wherein:
e) the at least one rectifying component has minimal characteristic forward resistance.

7. The passive matrix OLED display of claim 1, wherein the at least one rectifying component has accounts for at least 25% of the overall capacitance of the pixel, and wherein the forward resistance of the at least one rectifying component is equal to the forward resistance of the electroluminescent diode.

8. The passive matrix OLED display of claim 1, wherein:
a) the at least one rectifying component accounts for at least 25% of the overall capacitance of the pixel;
b) the at least one rectifying component has a rectification ratio of greater than 1;
c) the forward resistance of the at least one rectifying component is equal to the forward resistance of the electroluminescent diode;
d) the at least one rectifying component has, in the forward biased region after the cut-in voltage, an I/V response curve with an average slope at least 2 times greater than the average slope of the I/V response curve of the similar pixel lacking the at least one rectifying component; and
e) the at least one rectifying component has minimal characteristic forward resistance.

9. The passive matrix OLED display of claim 1, wherein the OLED is a COLED and comprises a cavity, wherein the cavity extends through an electroluminescent layer and a dielectric layer.

10. The passive matrix OLED display of claim 1, wherein the at least one rectifying component has a rectification ratio of greater than 1, and wherein the OLED is a COLED and comprises a cavity.

11. The passive matrix OLED display of claim 1, wherein the forward resistance of the at least one rectifying component is equal to the forward resistance of the electroluminescent diode, and wherein the OLED is a COLED and comprises a cavity.

12. The passive matrix OLED display of claim 1 comprising, in order:
(a) a transparent substrate;
(b) an anode;
(c) the at least one OLED pixel, wherein the at least one rectifying component of the at least one OLED pixel is a transparent thin film diode; and
(d) a cathode.

13. The passive matrix OLED display of claim 1, comprising, in order:
(a) a substrate layer
(b) a bottom electrode layer
(c) one or more semiconductor layers;
(d) a pixel bottom electrode layer;
(e) a dielectric layer;
(f) a pixel top electrode layer; and
(g) an electroluminescent layer, and further comprising:
(h) at least one cavity extending through the pixel top electrode and through the dielectric layer,
wherein electroluminescent material from the electroluminescent layer extends into the at least one cavity and contacts the dielectric layer, the pixel top electrode layer, and the bottom electrode layer.

14. The passive matrix OLED display of claim 1, comprising, in order:
(a) a substrate;
(b) a bottom electrode layer;
(c) a dielectric layer;
(d) a pixel top electrode layer; and
(e) an electroluminescent layer, and further comprising:
(i) at least one cavity extending through the pixel top electrode and through the dielectric layer, and defining a pattern in the pixel top electrode layer; and
(ii) a semiconductor layer contacting the pixel top electrode layer and separating the pixel top electrode layer from the electroluminescent layer,
wherein electroluminescent material from the electroluminescent layer extends into the at least one cavity and contacts the dielectric layer, the pixel top electrode layer, and the bottom electrode layer.

15. A passive matrix OLED display of claim 1, wherein:
(a) at least one OLED pixel comprises, in order, a bottom electrode layer, a dielectric layer, a pixel top electrode layer, and an electroluminescent layer, and further comprises a cavity extending through the dielectric layer and the top electrode layer; and
(b) the electroluminescent layer extends into the cavity and contacts the dielectric layer, the pixel top electrode layer, and the bottom electrode layer.

16. A passive matrix OLED display comprising an array of individually addressable OLED pixels arranged in column and row lines in an imaging area of the display, wherein:
(a) at least one OLED pixel comprises, in order, a bottom electrode layer, a dielectric layer, a pixel top electrode layer, and an electroluminescent layer, and further comprises a cavity extending through the dielectric layer and the top electrode layer; and
(b) the electroluminescent layer extends into the cavity and contacts the dielectric layer, the pixel top electrode layer, and the bottom electrode layer.

17. The passive matrix OLED display of claim 16, wherein the imaging area of the display has a diagonal dimension greater than 1 inch.

18. The passive matrix OLED display of claim 16, further comprising:
a) a cathode layer having a thickness greater than 0.1 micron;
b) an anode layer made of an anode material having a conductivity greater than ITO; and/or
c) a dielectric layer made of a dielectric material having a k-value greater than 1.

19. The passive matrix OLED display of claim 16, wherein the imaging area of the display has a diagonal dimension greater than 5 inches and wherein the OLED display further comprises a dielectric layer made of a dielectric material having a k-value greater than 1.

20. A method for forming the passive matrix OLED display of claim 1, the method comprising: forming each OLED pixel in the plurality of pixels by series-connecting the electroluminescent diode and the at least one rectifying component.
